(19) United States
(12) Patent Application Publication
(10) Pub. No.: US 2024/0431088 A1
(43) Pub. Date: Dec. 26, 2024

(54) SEMICONDUCTOR STORAGE DEVICE

(71) Applicant: Socionext Inc., Kanagawa (JP)

(72) Inventor: Masanobu HIROSE, Yokohama-shi (JP)

(21) Appl. No.: 18/825,831

(22) Filed: Sep. 5, 2024

Related U.S. Application Data
(63) Continuation of application No. PCT/JP2023/007124, filed on Feb. 27, 2023.

(30) Foreign Application Priority Data
Mar. 7, 2022 (JP) 2022-034206

(51) Int. Cl. H10B 10/00; G11C 11/412; G11C 11/419

(52) U.S. Cl. CPC H10B 10/12; G11C 11/412; G11C 11/419

(57) ABSTRACT

A 2-port SRAM cell includes load transistors, drive transistors, access transistors, a read drive transistor, and a read access transistor. Buried interconnects corresponding to write-bit lines, respectively are formed in a buried interconnect layer so as to extend in a first direction. Interconnects corresponding to a read-word line and a write-word line, respectively are formed in an interconnect layer above the buried interconnect layer so as to extend in a second direction.

### CROSS-REFERENCE TO RELATED APPLICATIONS

This is a continuation of International Application No. PCT/JP2023/007124 filed on Feb. 27, 2023, which claims priority to Japanese Patent Application No. 2022-034206 filed on Mar. 7, 2022. The entire disclosures of these applications are incorporated by reference herein.

### BACKGROUND

The present disclosure relates to a semiconductor storage device, and particularly to a layout structure of a 2-port static random access memory (SRAM) cell (hereinafter also simply referred to as a cell as appropriate).

SRAMs have been widely used for semiconductor integrated circuits.

In order to achieve high integration of a semiconductor integrated circuit, use of not an interconnect provided in a metal interconnect layer formed above a transistor as in the related art but an interconnect provided in a buried interconnect (BI) layer has been proposed.

R. Mathur et al, “Buried Bitline for sub-5 nm SRAM Design,” 2020 IEEE International Electron Devices Meeting (IEDM), December 2020, IEDM20-409-412 discloses a layout structure of a 1-port SRAM cell in which a bit line pair is provided in a buried interconnect layer.

### SUMMARY

However, no specific study has been conducted on the layout of a 2-port SRAM cell in which the bit lines are provided in the buried interconnect layer.

An object of the present disclosure is to provide a layout structure of a 2-port SRAM cell in which a bit line is provided in a buried interconnect layer.

A first aspect of the present disclosure is directed to a semiconductor storage device including a 2-port SRAM cell. The 2-port SRAM cell includes a first transistor having nodes, one of which is connected to a first power source that supplies a first voltage and the other one of which is connected to a first node, and having a gate connected to a second node, a second transistor having nodes, one of which is connected to the first power source and the other one of which is connected to the second node, and having a gate connected to the first node, a third transistor having nodes, one of which is connected to the first node and the other one of which is connected to a second power source that supplies a second voltage different from the first voltage, and having a gate connected to the second node, a fourth transistor having nodes, one of which is connected to the second node and the other one of which is connected to the second power source, and having a gate connected to the first node, a fifth transistor having nodes, one of which is connected to a first write-bit line and the other one of which is connected to the first node, and having a gate connected to a write-word line, a sixth transistor having nodes, one of which is connected to a second write-bit line forming a complementary bit line pair together with the first write-bit line and the other one of which is connected to the second node, and having a gate connected to the write-word line, a seventh transistor having one node connected to the second power source and a gate connected to the second node, and an eighth transistor having nodes, one of which is connected to the other node of the seventh transistor, the other node of which is connected to a read-bit line, and a gate connected to a read-word line, the first write-bit line has a first buried interconnect formed in a buried interconnect layer and extending in a first direction, the second write-bit line has a second buried interconnect formed in the buried interconnect layer and extending in the first direction, the write-word line has a first interconnect formed in a first interconnect layer above the buried interconnect layer and extending in a second direction perpendicular to the first direction, and the read-word line has a second interconnect formed in the first interconnect layer and extending in the second direction.

According to the present disclosure, the first and second buried interconnects corresponding to the first and second write-bit lines are formed in the buried interconnect layer, and the first and second interconnects each corresponding to the read-word line and the write-word line are formed in the first interconnect layer above the buried interconnect layer. Thus, by increasing the film thicknesses of the first and second buried interconnects, the resistance of the first and second write-bit lines can be reduced. This makes it possible to increase the speed of the operation of the semiconductor storage device and improve its write characteristics.

A second aspect of the present disclosure is directed to a semiconductor storage device including a 2-port SRAM cell. The 2-port SRAM cell includes a first transistor having nodes, one of which is connected to a first power source that supplies a first voltage and the other one of which is connected to a first node, and having a gate connected to a second node, a second transistor having nodes, one of which is connected to the first power source and the other one of which is connected to the second node, and having a gate connected to the first node, a third transistor having nodes, one of which is connected to the first node and the other one of which is connected to a second power source that supplies a second voltage different from the first voltage, and having a gate connected to the second node, a fourth transistor having nodes, one of which is connected to the second node and the other one of which is connected to the second power source, and having a gate connected to the first node, a fifth transistor having nodes, one of which is connected to a first write-bit line and the other one of which is connected to the first node, and having a gate connected to a write-word line, a sixth transistor having nodes, one of which is connected to a second write-bit line forming a complementary bit line pair together with the first write-bit line and the other one of which is connected to the second node, and having a gate connected to the write-word line, a seventh transistor having one node connected to the second power source and a gate connected to the second node, and an eighth transistor having nodes, one of which is connected to the other node of the seventh transistor, the other one of which is connected to a read-bit line, and a gate connected to a read-word line, the 2-port SRAM cell further includes a second buried power rail formed in the buried interconnect layer, connected to the second power source, and extending in the first direction, the first write-bit line has a first interconnect formed in a second interconnect layer above the buried interconnect layer and extending in the first direction, the second write-bit line has a second interconnect formed in the second interconnect layer and extending in the first direction, the write-word line has a third interconnect formed in a first interconnect layer above the second interconnect layer and extending in a second direction perpendicular to the first direction, and the read-word line has a fourth interconnect formed in the first interconnect layer and extending in the second direction.

According to the present disclosure, the second buried power rail for supplying the second voltage is formed in the buried interconnect layer, the first and second interconnects corresponding to the first and second write-bit lines are formed in the second interconnect layer above the buried interconnect layer, and the third and fourth interconnects corresponding to the read-word line and the write-word line are formed in the first interconnect layer above the second interconnect layer. For example, in a case where the interconnects corresponding to the first and second write-bit lines are formed in the buried interconnect layer, if the interconnect widths of these interconnects are increased, the arrangement interval of transistors in the 2-port SRAM cell needs to be increased, and for this reason, the area of the semiconductor storage device may be increased. On the other hand, in the present disclosure, the first and second interconnects corresponding to the first and second write-bit lines, respectively are formed in the second interconnect layer, and therefore, the interconnect widths of the first and second interconnects can be increased without moving each transistor in the 2-port SRAM cell. Further, the second buried power rail is formed in the buried interconnect layer, and therefore, the interconnect widths of the first and second interconnects in the second interconnect layer are not limited by the interconnect for supplying the second voltage. Thus, the interconnect widths of the first and second interconnects corresponding to the first and second write-bit lines, respectively can be increased, and therefore, the resistance of the first and second write-bit lines can be reduced, the speed of the operation of the semiconductor storage device can be increased, and the write characteristics of the semiconductor storage device can be improved.

According to the present disclosure, the speed of the operation of the semiconductor storage device can be increased, and its write characteristics can be improved.

### BRIEF DESCRIPTION OF THE DRAWINGS

FIG. 1, (a) and (b) are plan views showing an exemplary layout structure of a 2-port SRAM cell according to a first embodiment.

FIG. 2, (a) to (c) are sectional views showing the exemplary layout structure of the 2-port SRAM cell according to the first embodiment.

FIG. 3, (a) and (b) are sectional views showing the exemplary layout structure of the 2-port SRAM cell according to the first embodiment.

FIG. 4 is a circuit diagram showing the configuration of the 2-port SRAM cell according to the first embodiment.

FIG. 5, (a) and (b) are plan views showing another exemplary layout structure of the 2-port SRAM cell according to the first embodiment.

FIG. 6, (a) and (b) are plan views showing an exemplary layout structure of a 2-port SRAM cell according to a second embodiment.

FIG. 7, (a) and (b) are plan views showing an exemplary layout structure of a 2-port SRAM cell according to a third embodiment.

FIG. 8, (a) and (b) are plan views showing another exemplary layout structure of the 2-port SRAM cell according to the third embodiment.

### DETAILED DESCRIPTION

Embodiments will be described below in detail with reference to the drawings. The following embodiments assume that a semiconductor storage device includes a plurality of SRAM cells (in the present specification, hereinafter simply referred to as cells as appropriate) and that at least some of the plurality of SRAM cells include, for example, a nanosheet FET. The nanosheet FET is an FET using a thin sheet (nanosheet) through which current flows. The nanosheet is made of silicon, for example.

In the present disclosure, a semiconductor layer portion which is formed at each end of the nanosheet and which forms a terminal serving as the source or drain of the nanosheet FET will be referred to as a “pad.”

In the present disclosure, the SRAM cell includes a buried interconnect (BI) in a buried interconnect layer having an interconnect buried in a substrate or a shallow trench isolation (STI). In the following description, the interconnect provided in the buried interconnect layer may be referred to as a buried interconnect, and particularly, a power rail provided in the buried interconnect layer may be referred to as a buried power rail (BPR).

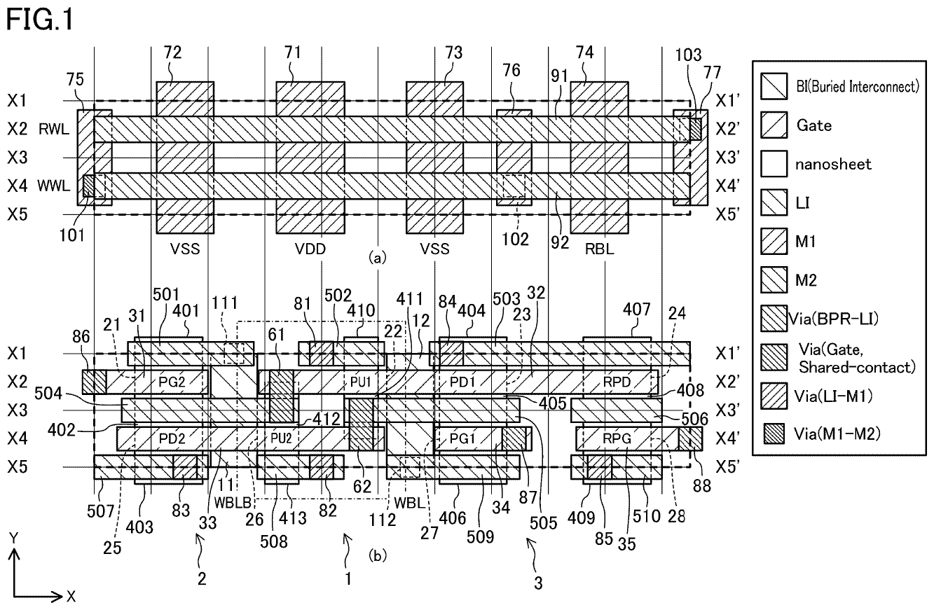

In the following description, in a plan view such as FIG. 1, a longitudinal direction is a Y-direction (first direction), a lateral direction is an X-direction (second direction), and a direction perpendicular to a substrate surface is a Z-direction. The “VDD” represents a power supply voltage, a high voltage power source itself, or a high voltage power line, and the “VSS” represents a power supply voltage, a low voltage power source itself, or a low voltage power line.

In the plan views and sectional views in the embodiments below, insulating films or the like may be omitted. In the plan views and sectional views in the embodiments below, the nanosheet and the pads on both sides thereof may be illustrated in the form of a simplified linear shape. In the present disclosure, the expressions such as “the same size” indicating that the size and the like are the same encompass a range of variation in manufacturing.

In the present disclosure, the source and drain of the transistor will be referred to as “nodes” of the transistor as appropriate. That is, one node of the transistor indicates the source or drain of the transistor, and both nodes of the transistor indicate the source and drain of the transistor.

In the following embodiments and variations thereof, the same reference characters are used to represent equivalent elements, and the description thereof will be omitted.

### First Embodiment

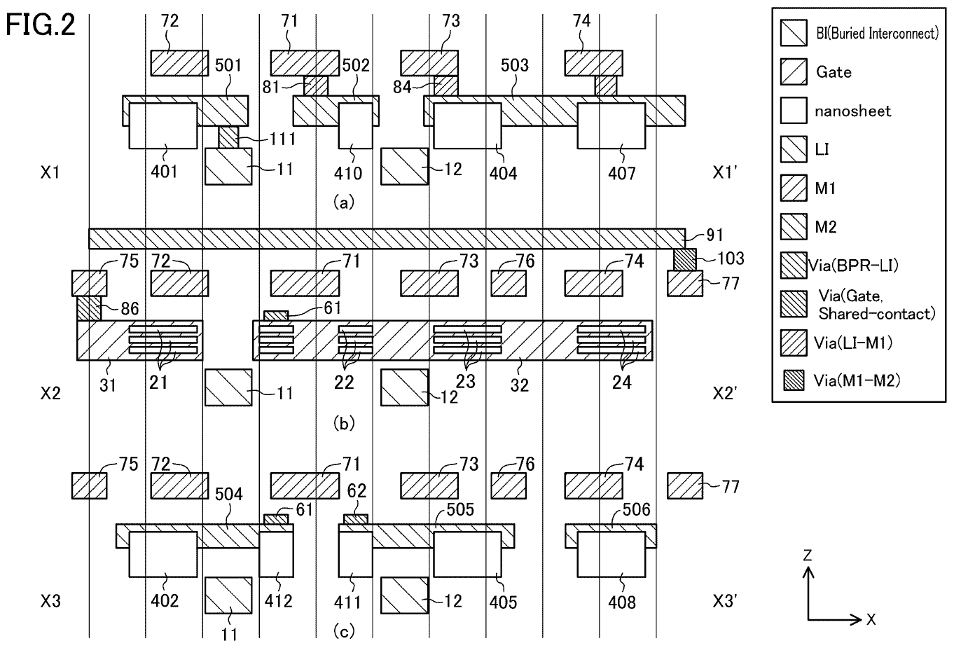

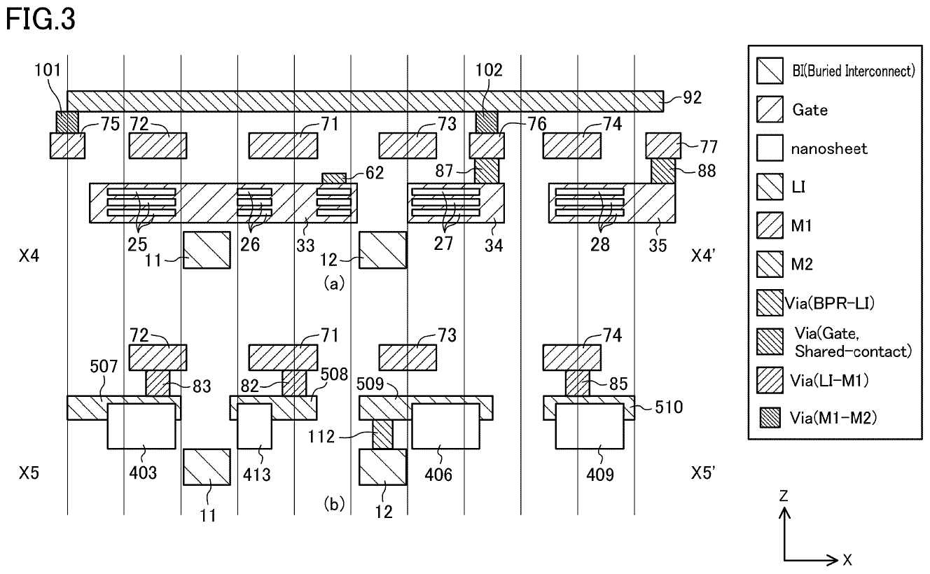

FIGS. 1A to 3B illustrate an exemplary layout structure of a 2-port SRAM cell according to a first embodiment. In FIG. 1, (a) and (b) are plan views, and In FIGS. 2 and 3, (a) to (c) and (a) and (b) are sectional views taken along the lateral direction in plan view. Specifically, In FIG. 1, (a) illustrates a cell upper portion which includes M1, M2 interconnect layers, and (b) illustrates a cell lower portion which is a layer below the M1, M2 interconnect layers and includes a nanosheet FET. In FIG. 2, (a) illustrates a section taken along line X1-X1′, (b) illustrates a section taken along line X2-X2′, and (c) illustrates a section taken along line X3-X3′, and in FIG. 3, (a) illustrates a section taken along line X4-X4′, and (b) illustrates a section taken along line X5-X5′.

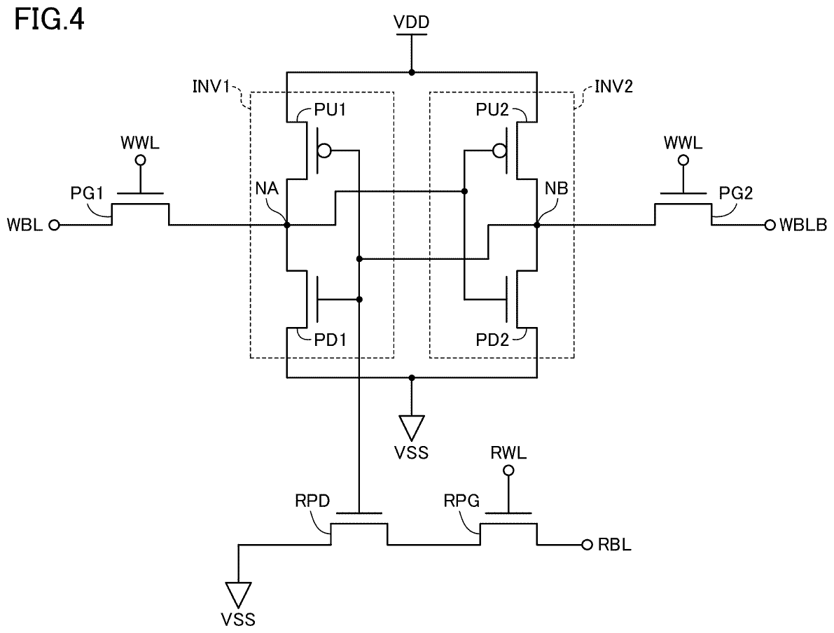

FIG. 4 is a circuit diagram illustrating the configuration of the 2-port SRAM cell according to the first embodiment. As illustrated in FIG. 4, the 2-port SRAM cell includes a 2-port memory cell circuit having load transistors PU1, PU2, drive transistors PD1, PD2, access transistors PG1, PG2, a read drive transistor RPD, and a read access transistor RPG. The load transistors PU1, PU2 are P-type FETs, and the drive transistors PD1, PD2, the access transistors PG1, PG2, the read drive transistor RPD, and the read access transistor RPG are N-type FETs.

The load transistor PU1 is provided between the power supply voltage VDD and a first node NA, and the drive transistor PD1 is provided between the first node NA and the power source VSS. The load transistor PU1 and the drive transistor PD1 have their gates connected to a second node NB to form an inverter INV1. The load transistor PU2 is provided between the power supply voltage VDD and the second node NB, and the drive transistor PD2 is provided between the second node NB and the power source VSS. The load transistor PU2 and the drive transistor PD2 have their gates connected to the first node NA to form an inverter INV2. That is, the output of one inverter is connected to the input of the other inverter, whereby a latch is formed.

The access transistor PG1 is provided between a write-bit line WBL and the first node NA, and has its gate connected to a write-word line WWL. The access transistor PG2 is provided between a write-bit line WBLB and the second node NB, and has its gate connected to a write-word line WWL. The write-bit lines WBL, WBLB form a complementary write-bit line pair.

The read drive transistor RPD has its source connected to the power source VSS, its gate connected to the second node NB, and its drain connected to the source of the read access transistor RPG. The read access transistor RPG has its gate connected to a read-word line RWL and its drain connected to a read-bit line RBL.

In the memory cell circuit of FIG. 4, when the write-bit lines WBL, WBLB forming the complementary write-bit line pair are driven to a high level and a low level, respectively, to drive the write-word line WWL to the high level, the high level is be written to the first node NA and the low level is written to the second node NB. On the other hand, when the write-bit lines WBL, WBLB are driven to the low level and the high level, respectively, to drive the write-word line WWL to the high level, the low level is written to the first node NA and the high level is written to the second node NB. Then, when the write-word line WWL is driven to the low level with the data written to the first and the second nodes NA, NB, a latch state is determined and the data written to the first and the second nodes NA, NB is retained.

When the read-bit line RBL is pre-charged to a high level, and the read-word line RWL is driven to a high level, the state of the read-bit line RBL is determined according to the data written to the second node NB, and thus data can be read out from the memory cell. Specifically, when the second node NB is at the high level, the read-bit line RBL is discharged to the low level. On the other hand, when the second node NB is at the low level, the read-bit line RBL maintains the high level.

As described above, the 2-port SRAM cell has a function of writing and retaining data to and in the 2-port SRAM cell and reading out data from the 2-port SRAM cell by controlling the write-bit lines WBL, WBLB, the read-bit line RBL, the write-word line WWL, and the read-word line RWL.

In the following description, solid lines running longitudinally and laterally in, e.g., the plan view of FIG. 1 and solid lines running longitudinally in, e.g., the sectional view of FIG. 2 indicate a grid used for arranging components at the time of designing. Cells of the grid are arranged at equal intervals in the X-direction, and are arranged at equal intervals in the Y-direction. The intervals of the cells of the grid in the X-direction and those in the Y-direction may be the same or different. The intervals of the cells of the grid may be different among layers. Further, each component is not necessarily disposed on the grid. For the sake of reduction in manufacturing variations, each component is preferably disposed on the grid.

Dotted lines surrounding the cell in, e.g., the plan view of FIG. 1 indicate a cell frame of the SRAM cell (outer edge of the SRAM cell). The SRAM cell is disposed such that its cell frame comes into contact with a cell frame of an adjacent cell in the X-direction or the Y-direction.

In, e.g., the plan view of FIG. 1, the SRAM cells inverted in the X-direction are arranged on both sides of the SRAM cell in the X-direction. The SRAM cells inverted in the Y-direction are arranged on both sides of the SRAM cell in the Y-direction.

As illustrated in (b) of FIG. 1, buried interconnects 11, 12 extending in the Y-direction are formed in the buried interconnect layer over both upper and lower ends of the cell in the drawing. Specifically, the buried interconnect 11 is formed between a nanosheet 25 (21) and a nanosheet 26, which will be described later, in plan view. The buried interconnect 12 is formed between a nanosheet 22 and a nanosheet 23 (27), which will be described later, in plan view. The buried interconnects 11, 12 correspond to the write-bit lines WBLB, WBL, respectively.

The load transistors PU1, PU2 are formed on an N-well 1. The access transistor PG2 and the drive transistor PD2 are formed on a P-type substrate 2. The drive transistor PD1, the access transistor PG1, the read drive transistor RPD, and the read access transistor RPG are formed on a P-type substrate 3.

As illustrated in (b) of FIG. 1, the nanosheets 21 to 28 extending in the X-direction and the Y-direction are formed. The nanosheets 21 to 24 are arranged in the X-direction in the order of the nanosheets 21 to 24. The nanosheets 25 to 28 are arranged in the X-direction in the order of the nanosheets 25 to 28. The nanosheets 21, 25 are arranged in the Y-direction. The nanosheets 23, 27 are arranged in the Y-direction. The nanosheets 24, 28 are arranged in the Y-direction. The width of the nanosheet 21, 23, 24, 25, 27, 28 in the X-direction is twice the width of the nanosheet 22, 26 in the X-direction.

The nanosheets 21 to 28 form the respective channel portions of the access transistor PG2, the load transistor PU1, the drive transistor PD1, the read drive transistor RPD, the drive transistor PD2, the load transistor PU2, the access transistor PG1, and the read access transistor RPG.

As illustrated in (b) of FIG. 2 and (a) of FIG. 3, each of the nanosheets 21 to 28 includes three semiconductor sheets (nanosheets). Each of the nanosheets 21 to 28 is disposed such that the nanosheets forming each of the nanosheets 21 to 28 overlap each other in plan view and are separated from each other in the Z-direction. That is, the nanosheet FET in the 2-port SRAM cell according to the present embodiment includes three nanosheets.

As illustrated in (b) of FIG. 1, gate interconnects (Gate) 31 to 35 extend in the X-direction and the Z-direction. The gate interconnects 31, 32 are arranged in the X-direction, and the gate interconnects 33 to 35 are arranged in the X-direction.

The gate interconnect 31 overlaps the nanosheet 21 in plan view. The gate interconnect 32 overlaps the nanosheets 22 to 24 in plan view. The gate interconnect 33 overlaps the nanosheets 25, 26 in plan view. The gate interconnect 34 overlaps the nanosheet 27 in plan view. The gate interconnect 35 overlaps the nanosheet 28 in plan view.

The gate interconnect 31 serves as the gate of the access transistor PG2. The gate interconnect 32 serves as the gates of the load transistor PU1, the drive transistor PD1, and the read drive transistor RPD. The gate interconnect 33 serves as the gates of the drive transistor PD2 and the load transistor PU2. The gate interconnect 34 serves as the gate of the access transistor PG1. The gate interconnect 35 serves as the gate of the read access transistor RPG.

Pads 401 to 409 doped with an N-type semiconductor are formed at the upper end of the nanosheet 21 in the drawing, between the nanosheets 21, 25, at the lower end of the nanosheet 25 in the drawing, at the upper end of the nanosheet 23 in the drawing, between the nanosheets 23, 27, at the lower end of the nanosheet 27 in the drawing, at the upper end of the nanosheet 24 in the drawing, between the nanosheets 24, 28, and at the lower end of the nanosheet 28 in the drawing, respectively. The pads 401, 402 form the node of the access transistor PG2. The pads 402, 403 form the node of the drive transistor PD2. The pads 404, 405 form the node of the drive transistor PD1. The pads 405, 406 form the node of the access transistor PG1. The pads 407, 408 form the node of the read drive transistor RPD. The pads 408, 409 form the node of the read access transistor RPG.

Pads 410 to 413 doped with a P-type semiconductor are formed at the upper end of the nanosheet 22 in the drawing, the lower end of the nanosheet 22 in the drawing, the upper end of the nanosheet 26 in the drawing, and the lower end of the nanosheet 26 in the drawing, respectively. The pads 410, 411 form the node of the load transistor PU1. The pads 412, 413 form the node of the load transistor PU2.

In a local interconnect layer, local interconnects (LIs) 501 to 510 extending in the X-direction are formed. The local interconnect 501 is connected to the pad 401. The local interconnect 502 is connected to the pad 410. The local interconnect 503 is connected to the pads 404, 407. The local interconnect 504 is connected to the pads 402, 412. The local interconnect 505 is connected to the pads 405, 411. The local interconnect 506 is connected to the pad 408. The local interconnect 507 is connected to the pad 403. The local interconnect 508 is connected to the pad 413. The local interconnect 509 is connected to the pad 406. The local interconnect 510 is connected to the pad 409.

The local interconnect 501 is connected to the buried interconnect 11 through a contact (Via) 111. The local interconnect 509 is connected to the buried interconnect 12 through a contact 112.

The local interconnect 504 is connected to the gate interconnect 32 through a shared-contact 61. The local interconnect 505 is connected to the gate interconnect 33 through a shared-contact 62. The gate interconnect 33, the local interconnect 505, and the shared-contact 62 correspond to the first node NA. The gate interconnect 32, the local interconnect 504, and the shared-contact 61 correspond to the second node NB.

As illustrated in (a) of FIG. 1, in the M1 interconnect layer (second interconnect layer), interconnects 71 to 74 extending in the Y-direction are formed over both upper and lower ends of the cell in the drawing. Further, interconnects 75 to 77 are formed. The interconnect 71 supplies the power supply voltage VDD. The interconnects 72, 73 supply the power supply voltage VSS. The interconnect 74 corresponds to the read-bit line RBL.

The interconnect 71 is connected to the local interconnect 502 through a contact (Via) 81, and is connected to the local interconnect 508 through a contact 82. The interconnect 72 is connected to the local interconnect 507 through a contact 83. The interconnect 73 is connected to the local interconnect 503 through a contact 84. The interconnect 74 is connected to the local interconnect 510 through a contact 85. The interconnect 75 is connected to the gate interconnect 31 through a contact (Gate-contact) 86. The interconnect 76 is connected to the gate interconnect 34 through a contact 87. The interconnect 77 is connected to the gate interconnect 35 through a contact 88.

As illustrated in (a) and (b) of FIG. 1, the interconnect 72 and the buried interconnect 11 partially overlap with each other in plan view. The interconnect 73 and the buried interconnect 12 partially overlap with each other in plan view. The interconnects 71 to 73 have interconnect widths greater than those of the buried interconnects 12, 11 in plan view.

Interconnects 91, 92 extending in the X-direction from the left end to the right end of the cell in the drawing are formed in the M2 interconnect layer (first interconnect layer) above the M1 interconnect layer. The interconnects 91, 92 correspond to the read-word line RWL and the write-word line WWL, respectively. The interconnect 91 is connected to the interconnect 77 through a contact 103. The interconnect 92 is connected to the interconnect 75 through a contact 101, and is connected to the interconnect 76 through a contact 102.

With the above configuration, in the load transistor PU1, the pad 410 is connected to the interconnect 71 for supplying the power supply voltage VDD, the pad 411 is connected to the local interconnect 505 (first node NA), and the gate interconnect 32 is connected to the shared-contact 61 (second node NB). In the load transistor PU2, the pad 413 is connected to the interconnect 71 for supplying the power supply voltage VDD, the pad 412 is connected to the local interconnect 504 (second node NB), and the gate interconnect 33 is connected to the shared-contact 62 (first node NA). In the drive transistor PD1, the pad 405 is connected to the local interconnect 505 (first node NA), the pad 404 is connected to the interconnect 73 for supplying the power supply voltage VSS, and the gate interconnect 32 is connected to the shared-contact 61 (second node NB). In the drive transistor PD2, the pad 402 is connected to the local interconnect 504 (second node NB), the pad 403 is connected to the interconnect 72 for supplying the power supply voltage VSS, and the gate interconnect 33 is connected to the shared-contact 62 (first node NA). In the access transistor PG1, the pad 406 is connected to the buried interconnect 12 (write-bit line WBL), the pad 405 is connected to the local interconnect 505 (first node NA), and the gate interconnect 34 is connected to the interconnect 92 (write-word line WWL). In the access transistor PG2, the pad 401 is connected to the buried interconnect 11 (write-bit line WBLB), the pad 402 is connected to the local interconnect 504 (second node NB), and the gate interconnect 31 is connected to the interconnect 92 (write-word line WWL). In the read drive transistor RPD, the pad 407 is connected to the interconnect 73 for supplying the power supply voltage VSS, and the gate interconnect 32 is connected to the shared-contact 61 (second node NB). The read access transistor RPG shares the pad 408 with the read drive transistor RPD, the pad 409 is connected to the interconnect 74 (read-bit line RBL), and the gate interconnect 35 is connected to the interconnect 91 (read-word line RWL). The buried interconnects 11, 12 are formed in the buried interconnect layer so as to extend in the Y-direction, and the interconnects 91, 92 are formed in the M2 interconnect layer above the buried interconnect layer so as to extend in the X-direction.

That is, the buried interconnects 11, 12 corresponding to the write-bit lines WBLB, WBL, respectively are formed in the buried interconnect layer, and the interconnects 91, 92 corresponding to the read-word line RWL and the write-word line WWL, respectively are formed in the M2 interconnect layer above the buried interconnect layer. Thus, by increasing the film thicknesses (lengths in the Z-direction) of the buried interconnects 11, 12, the resistance of the write-bit lines WBLB, WBL can be reduced. This makes it possible to improve the write characteristics of the semiconductor storage device, which leads to a speed increase and a voltage decrease.

The buried interconnects 11, 12 corresponding to the write-bit lines WBLB, WBL, respectively are formed in the buried interconnect layer, and the interconnects 91, 92 corresponding to the read-word line RWL and the write-word line WWL, respectively are formed in the M2 interconnect layer. Thus, the distances between the write-bit lines WBL, WBLB and the read-word line RWL and the write-word line WWL in the Z-direction increase. Thus, coupling noise between the write-bit lines WBL, WBLB and the read-word line RWL and the write-word line WWL can be reduced, and therefore, the write characteristics and read characteristics of the semiconductor storage device can be improved. Specifically, when the write-word line WWL changes from the low level to the high level and the write-bit line WBL or the write-bit line WBLB changes from the high level to the low level, a delay in the rise time of the write-word line WWL due to coupling between the interconnects can be reduced. Similarly, when the read-word line RWL changes from the low level to the high level and the read-bit line RBL changes from the high level to the low level, a delay in the rise time of the read-word line RWL due to coupling between the interconnects can be reduced.

The buried interconnects 11, 12 corresponding to the write-bit lines WBLB, WBL, respectively are formed in the buried interconnect layer, and therefore, the interconnect widths of the interconnects 71 to 73 in the M1 interconnect layer can be increased. Accordingly, the power source to the SRAM cells can be enhanced, and therefore, the stability of the operation of the semiconductor storage device can be improved.

### (Variations)

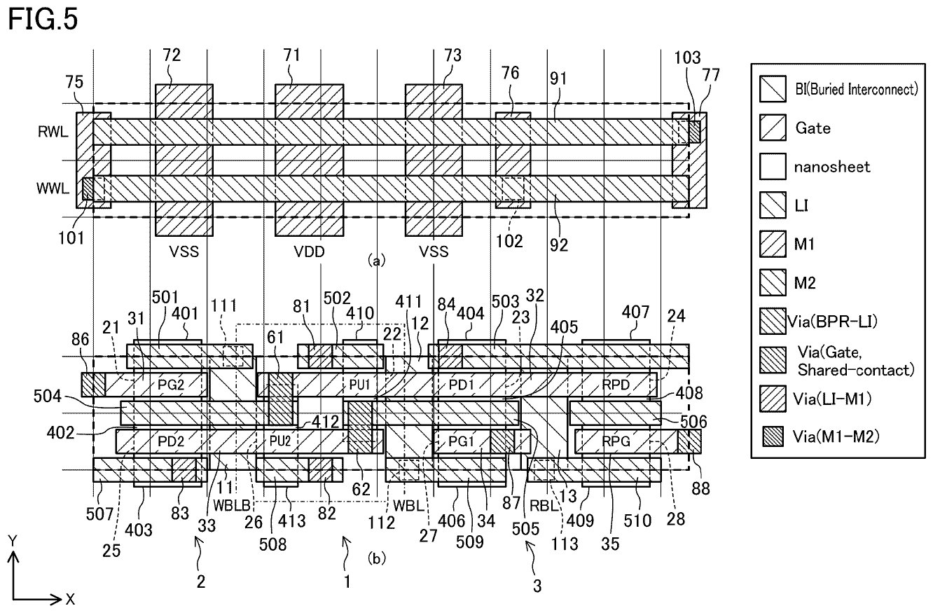

In FIG. 5, (a) and (b) are plan views illustrating another exemplary layout structure of the 2-port SRAM cell according to the first embodiment. Specifically, in FIG. 5, (a) illustrates a cell upper portion, and (b) illustrates a cell lower portion. In FIG. 5, (a) and (b), as compared with (a) and (b) in FIG. 1, the interconnect 74 in the M1 interconnect layer is omitted, and a buried interconnect 13 extending in the Y-direction is formed in the buried interconnect layer.

Specifically, the buried interconnect 13 is formed between the nanosheet 23 (27) and the nanosheet 24 (28) in plan view. The buried interconnect 13 corresponds to the read-bit line RBL. The buried interconnect 13 is connected to the local interconnect 510 through a contact 113.

In this variation, the buried interconnect 13 corresponding to the read-bit line RBL is formed in the buried interconnect layer. Thus, by increasing the film thickness (length in the Z-direction) of the buried interconnect 13, the resistance of the read-bit line RBL can be reduced. This makes it possible to improve the read speed of the semiconductor storage device.

The buried interconnect 13 corresponding to the read-bit line RBL is formed in the buried interconnect layer, and therefore, the interconnect widths of the interconnects 71 to 73 can be increased. Accordingly, the power source to the SRAM cells can be enhanced, and therefore, the stability of the operation of the semiconductor storage device can be improved.

It is not necessary to form an interconnect corresponding to the read-bit line RBL in the M1 interconnect layer, and therefore, other interconnects can be arranged in the M1 interconnect layer. This makes it possible to improve the degree of freedom in designing the semiconductor storage device.

### Second Embodiment

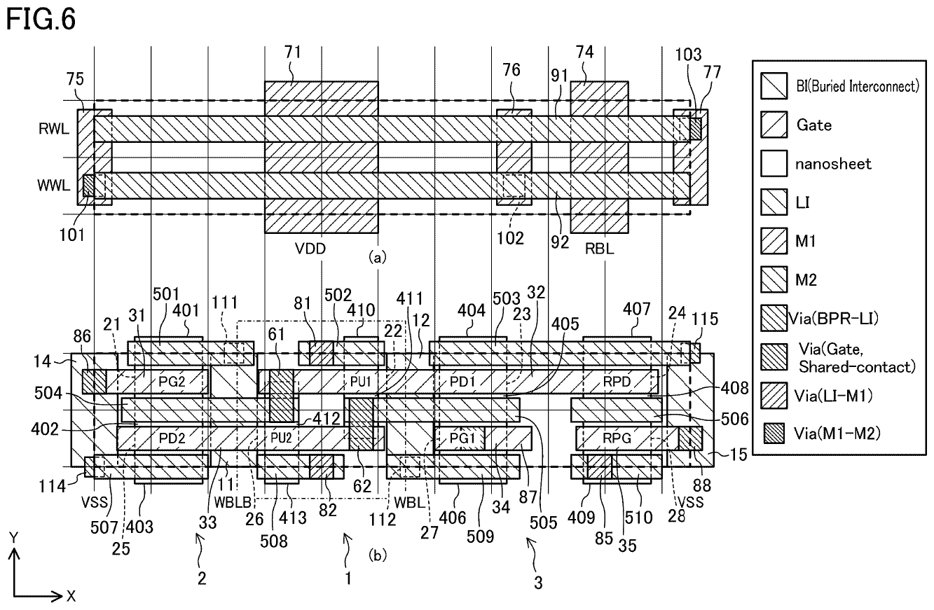

In FIG. 6, (a) and (b) are plan views illustrating an exemplary layout structure of a 2-port SRAM cell according to a second embodiment. Specifically, in FIG. 6, (a) illustrates a cell upper portion, and (b) illustrates a cell lower portion. In FIG. 6, (a) and (b), as compared with (a) and (b) in FIG. 1, buried power rails 14, 15 are formed in a buried interconnect layer, and interconnects 72, 73 in a M1 interconnect layer are omitted.

As illustrated in (b) of FIG. 6, the buried power rails 14, 15 extending in the Y-direction are formed in the buried interconnect layer over both upper and lower ends of a cell in the drawing. The buried power rails 14, 15 supply a power supply voltage VSS. The buried power rails 14, 15 are formed at both left and right ends of the cell in the drawing. The buried power rails 14, 15 are shared with 2-port SRAM cells arranged on the left and right sides of the 2-port SRAM cell.

The buried power rail 14 is connected to a local interconnect 507 through a contact 114. The buried power rail 15 is connected to a local interconnect 503 through a contact 115. An interconnect 71 has an interconnect width greater than those of buried interconnects 11, 12 and those of the buried power rails 14, 15 in plan view.

With the above configuration, in a load transistor PU1, a pad 410 is connected to the interconnect 71 for supplying a power supply voltage VDD, a pad 411 is connected to a local interconnect 505 (first node NA), and a gate interconnect 32 is connected to a shared-contact 61 (second node NB). In a load transistor PU2, a pad 413 is connected to the interconnect 71 for supplying the power supply voltage VDD, a pad 412 is connected to a local interconnect 504 (second node NB), and a gate interconnect 33 is connected to a shared-contact 62 (first node NA). In a drive transistor PD1, a pad 405 is connected to the local interconnect 505 (first node NA), a pad 404 is connected to the buried power rail 15 for supplying the power supply voltage VSS, and the gate interconnect 32 is connected to the shared-contact 61 (second node NB). In a drive transistor PD2, a pad 402 is connected to the local interconnect 504 (second node NB), a pad 403 is connected to the buried power rail 14 for supplying the power supply voltage VSS, and the gate interconnect 33 is connected to the shared-contact 62 (first node NA). In an access transistor PG1, a pad 406 is connected to the buried interconnect 12 (write-bit line WBL), a pad 405 is connected to the local interconnect 505 (first node NA), and a gate interconnect 34 is connected to an interconnect 92 (write-word line WWL). In an access transistor PG2, a pad 401 is connected to the buried interconnect 11 (write-bit line WBLB), a pad 402 is connected to the local interconnect 504 (second node NB), and a gate interconnect 31 is connected to the interconnect 92 (write-word line WWL). In a read drive transistor RPD, a pad 407 is connected to the buried power rail 15 for supplying the power supply voltage VSS, and the gate interconnect 32 is connected to the shared-contact 61 (second node NB). A read access transistor RPG shares a pad 408 with the read drive transistor RPD, a pad 409 is connected to an interconnect 74 (read-bit line RBL), and a gate interconnect 35 is connected to an interconnect 91 (read-word line RWL). The buried interconnects 11, 12 are formed in the buried interconnect layer so as to extend in the Y-direction. The interconnects 91, 92 are formed in a M2 interconnect layer above the buried interconnect layer so as to extend in the X-direction.

That is, the buried interconnects 11, 12 corresponding to the write-bit lines WBLB, WBL, respectively are formed in the buried interconnect layer, and the interconnects 91, 92 corresponding to the read-word line RWL and the write-word line, respectively are formed in the M2 interconnect layer above the buried interconnect layer. Thus, by increasing the film thicknesses (lengths in the Z-direction) of the buried interconnects 11, 12, the resistance of the write-bit lines WBLB, WBL can be reduced. This makes it possible to improve the write characteristics of the semiconductor storage device, which leads to a speed increase and a voltage decrease.

The buried interconnects 11, 12 corresponding to the write-bit lines WBLB, WBL, respectively are formed in the buried interconnect layer, and the interconnects 91, 92 corresponding to the read-word line RWL and the write-word line WWL, respectively are formed in the M2 interconnect layer. Thus, the distances between the write-bit lines WBL, WBLB and the read-word line RWL and the write-word line WWL in the Z-direction increase. Thus, coupling noise between the write-bit lines WBL, WBLB and the read-word line RWL and the write-word line WWL can be reduced, and therefore, the write characteristics and read characteristics of the semiconductor storage device can be improved. Specifically, when the write-word line WWL changes from the low level to the high level and the write-bit line WBL or the write-bit line WBLB changes from the high level to the low level, a delay in the rise time of the write-word line WWL due to coupling between the interconnects can be reduced. Similarly, when the read-word line RWL changes from the low level to the high level and the read-bit line RBL changes from the high level to the low level, a delay in the rise time of the read-word line RWL due to coupling between the interconnects can be reduced.

The buried interconnects 11, 12 corresponding to the write-bit lines WBL, WBLB, respectively and the buried power rails 14, 15 for supplying the power supply voltage VSS are formed in the buried interconnect layer, and therefore, the interconnect width of the interconnect 71 of the M1 interconnect layer for supplying the power supply voltage VDD can be increased. Accordingly, the power source to the 2-port SRAM cells can be enhanced, and therefore, the stability of the operation of the semiconductor storage device can be improved.

The buried power rails 14, 15 formed at both left and right ends of the cell in the drawing are shared with the 2-port SRAM cells arranged on the left and right sides of the 2-port SRAM cell. Accordingly, the power source to the 2-port SRAM cells can be enhanced, and therefore, the stability of the operation of the semiconductor storage device can be improved.

It is not necessary to form interconnects corresponding to the write-bit lines WBL, WBLB, respectively and an interconnect for supplying the power supply voltage VDD in the M1 interconnect layer, and therefore, the degree of freedom in designing the semiconductor storage device is improved.

As in (a) and (b) of FIG. 5, the interconnect 74 in the M1 interconnect layer may be omitted, and a buried interconnect 13 corresponding to the read-bit line RBL may be formed in the buried interconnect layer. Accordingly, effects similar to those of (a) and (b) in FIG. 5 can be obtained.

### Third Embodiment

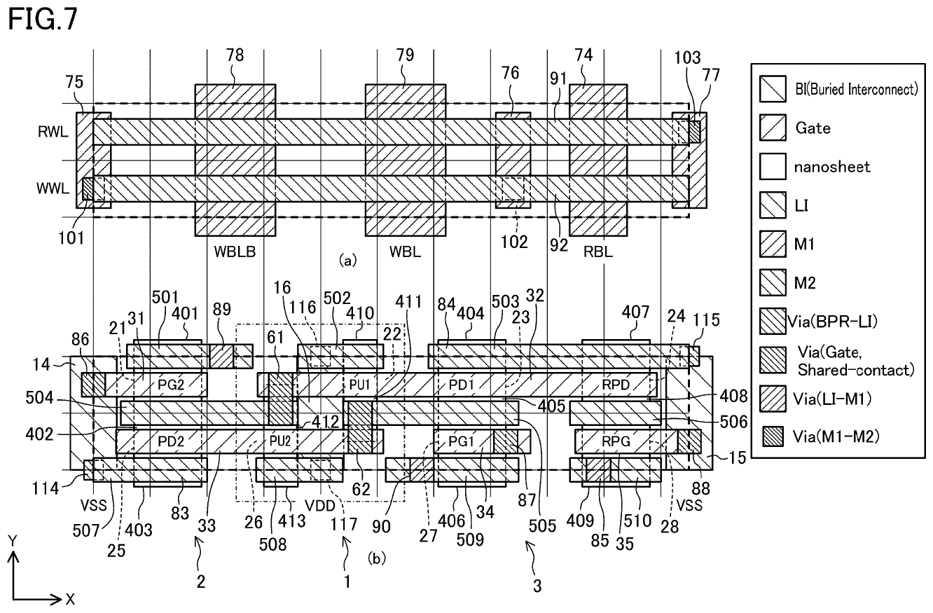

In FIG. 7, (a) and (b) are plan views illustrating an exemplary layout structure of a 2-port SRAM cell according to a third embodiment. Specifically, in FIG. 7, (a) illustrates a cell upper portion, and (b) illustrates a cell lower portion. In FIG. 7, (a) and (b), as compared with (a) and (b) in FIG. 1, buried interconnects 11, 12 in a buried interconnect layer are omitted, and buried power rails 14 to 16 are formed. Interconnects 71 to 73 in a M1 interconnect layer are omitted, and interconnects 78, 79 are formed.

As illustrated in (b) of FIG. 7, the buried power rails 14 to 16 extending in the Y-direction are formed in the buried interconnect layer over both upper and lower ends of a cell in the drawing. The buried power rails 14, 15 are each formed at both left and right ends of the cell in the drawing, and a buried power rail 16 is formed at a center portion of the cell in the drawing. The buried power rails 14, 15 supply a power supply voltage VSS. The buried power rail 16 supplies a power supply voltage VDD. The buried power rail 16 is formed between nanosheets 22, 26 in plan view. The buried power rails 14, 15 are shared with 2-port SRAM cells arranged on the left and right sides of the 2-port SRAM cell.

The buried power rail 14 is connected to a local interconnect 507 through a contact 114. The buried power rail 15 is connected to a local interconnect 503 through a contact 115. The buried power rail 16 is connected to a local interconnect 502 through a contact 116, and is connected to a local interconnect 508 through a contact 117.

As illustrated in (a) of FIG. 7, in the M1 interconnect layer, the interconnects 78, 79 extending in the Y-direction are formed over both upper and lower ends of the cell in the drawing. The interconnects 78, 79 correspond to write-bit lines WBLB, WBL, respectively.

The interconnect 78 is connected to a local interconnect 501 through a contact 89. The interconnect 79 is connected to a local interconnect 509 through a contact 90.

With the above configuration, in a load transistor PU1, a pad 410 is connected to the buried power rail 16 for supplying the power supply voltage VDD, a pad 411 is connected to a local interconnect 505 (first node NA), and a gate interconnect 32 is connected to a shared-contact 61 (second node NB). In a load transistor PU2, a pad 413 is connected to the buried power rail 16 for supplying the power supply voltage VDD, a pad 412 is connected to a local interconnect 504 (second node NB), and a gate interconnect 33 is connected to a shared-contact 62 (first node NA). In a drive transistor PD1, a pad 405 is connected to the local interconnect 505 (first node NA), a pad 404 is connected to the buried power rail 15 for supplying the power supply voltage VSS, and the gate interconnect 32 is connected to the shared-contact 61 (second node NB). In a drive transistor PD2, a pad 402 is connected to the local interconnect 504 (second node NB), a pad 403 is connected to the buried power rail 14 for supplying the power supply voltage VSS, and the gate interconnect 33 is connected to the shared-contact 62 (first node NA). In an access transistor PG1, a pad 406 is connected to the interconnect 79 (write-bit line WBL), a pad 405 is connected to the local interconnect 505 (first node NA), and a gate interconnect 34 is connected to an interconnect 92 (write-word line WWL). In an access transistor PG2, a pad 401 is connected to the interconnect 78 (write-bit line WBLB), a pad 402 is connected to the local interconnect 504 (second node NB), and a gate interconnect 31 is connected to the interconnect 92 (write-word line WWL). In a read drive transistor RPD, a pad 407 is connected to the buried power rail 15 for supplying the power supply voltage VSS, and the gate interconnect 32 is connected to the shared-contact 61 (second node NB). A read access transistor RPG shares a pad 408 with the read drive transistor RPD, a pad 409 is connected to an interconnect 74 (read-bit line RBL), and a gate interconnect 35 is connected to an interconnect 91 (read-word line RWL). The buried power rails 14 to 16 are formed in the buried interconnect layer so as to extend in the Y-direction. The interconnects 78, 79 are formed in the M1 interconnect layer above the buried interconnect layer so as to extend in the Y-direction. The interconnects 91, 92 are formed in a M2 interconnect layer above the M1 interconnect layer so as to extend in the X-direction.

That is, the buried power rails 14, 15 for supplying the power supply voltage VSS and the buried power rail 16 for supplying the power supply voltage VDD are formed in the buried interconnect layer, the interconnects 78, 79 corresponding to the write-bit lines WBLB, WBL, respectively are formed in the M1 interconnect layer, and the interconnects 91, 92 corresponding to the read-word line RWL and the write-word line, respectively are formed in the M2 interconnect layer above the M1 interconnect layer. For example, in a case where the interconnects corresponding to the write-bit lines WBLB, WBL are formed in the buried interconnect layer, if the interconnect widths of these interconnects are increased, the arrangement interval of transistors in the 2-port SRAM cell needs to be increased, and for this reason, the area of the semiconductor storage device may be increased. On the other hand, in the present embodiment, the interconnects 78, 79 corresponding to the write-bit lines WBLB, WBL, respectively are formed in the M1 interconnect layer, and therefore, the interconnect widths of the interconnects 78, 79 can be increased without increasing the arrangement interval of the transistors. Further, the buried power rails 14, 15 for supplying the power supply voltage VSS and the buried power rail 16 for supplying the power supply voltage VDD are formed in the buried interconnect layer, and therefore, the interconnect widths of the interconnects 78, 79 in the M1 interconnect layer are not limited by the interconnects for supplying the power supply voltages VDD, VSS. Thus, the interconnect widths of the interconnects 78, 79 corresponding to the write-bit lines WBLB, WBL, respectively can be increased, and therefore, the resistance of the write-bit lines WBLB, WBL can be reduced and the write characteristics of the semiconductor storage device can be improved, which leads to a speed increase and a voltage decrease.

The interconnects 78, 79 corresponding to the write-bit lines WBLB, WBL, respectively are formed in the M1 interconnect layer, and therefore, the degree of freedom in the interconnect widths, intervals, and arrangements of the interconnects 78, 79 is improved as compared with that in a case where the interconnects corresponding to the write-bit lines WBLB, WBL, respectively are formed in the buried interconnect layer. Thus, optimization of the write characteristics of the semiconductor storage device, which leads to a speed increase and a voltage decrease, is facilitated.

The buried power rails 14, 15 formed at both left and right ends of the cell in the drawing are shared with the 2-port SRAM cells arranged on the left and right sides of the 2-port SRAM cell. Accordingly, the power source to the 2-port SRAM cells can be enhanced, and therefore, the stability of the operation of the semiconductor storage device can be improved.

The buried power rails 14, 15 for supplying the power supply voltage VSS and the buried power rail 16 for supplying the power supply voltage VDD are formed in the buried interconnect layer, and therefore, the interconnects for supplying the power supply voltages VDD, VSS do not need to be formed in the M1 interconnect layer. This makes it possible to arrange other interconnects in a free space in the M1 interconnect layer and thus improve the degree of freedom in designing the semiconductor storage device.

As in (a) and (b) of FIG. 5, the interconnect 74 in the M1 interconnect layer may be omitted, and a buried interconnect 13 corresponding to the read-bit line RBL may be formed in the buried interconnect layer. Accordingly, effects similar to those of (a) and (b) in FIG. 5 can be obtained.

### (Variations)

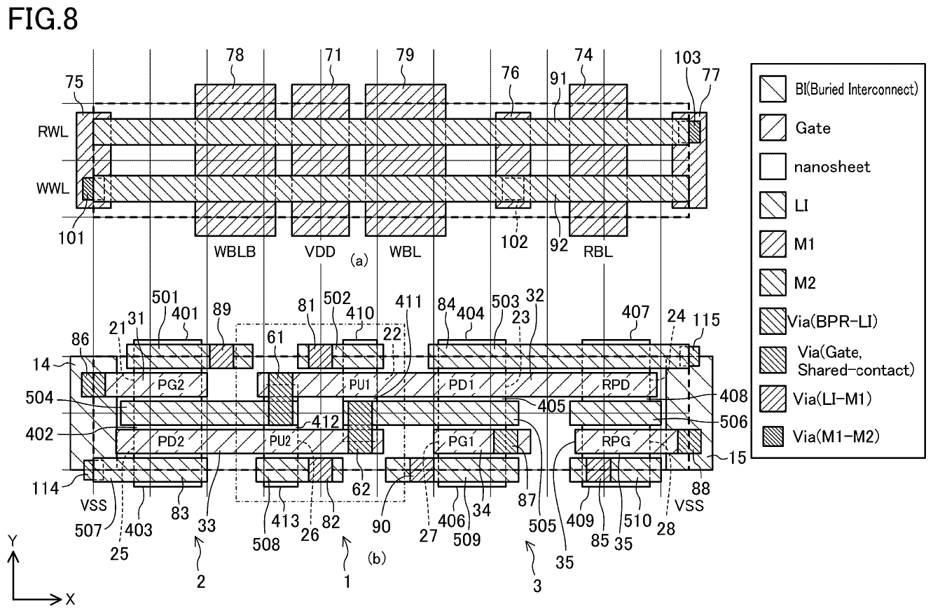

In FIG. 8, (a) and (b) are plan views illustrating another exemplary layout structure of the 2-port SRAM cell according to the third embodiment. Specifically, in FIG. 8, (a) illustrates a cell upper portion, and (b) illustrates a cell lower portion. In FIG. 8, (a) and (b), as compared with (a) and (b) in FIG. 7, the buried power rail 16 in the buried interconnect layer is omitted, and an interconnect 71 extending in the Y-direction is formed in the M1 interconnect layer.

In the present variation, the interconnect 71 for supplying the power supply voltage VDD is formed in the M1 interconnect layer. The interconnect 71 is formed between the interconnects 78, 79 in plan view. Accordingly, crosstalk noise between the interconnects 78, 79 corresponding to the write-bit lines WBLB, WBL, respectively is reduced so that the write operation of the semiconductor storage device can be stably performed at a higher speed.

In addition, effects similar to those of (a) and (b) in FIG. 7 can be obtained.

In addition to the M1 interconnect layer, the buried power rail 16 for supplying the power supply voltage VDD may also be formed in the buried interconnect layer. Accordingly, the power source to the semiconductor storage device can be enhanced, and therefore, the operation of the semiconductor storage device can be stabilized.

In the above embodiments and variations, each transistor includes the three nanosheets, but some or all of the transistors may include a single nanosheet, or two or four or more nanosheets.

In the above embodiments and variations, the sectional shape of the nanosheet is rectangular, but is not limited to this shape. For example, the shape may be square, circular, or elliptical.

In the above embodiments and variations, the shared-contacts 61, 62 may be manufactured in the same process as that for the contact (Gate-Contact) and the local interconnect, or may be manufactured in a different process.

In the above embodiments and variations, the width of each of the nanosheets 21, 23, 24, 25, 27, 28 in the X-direction is twice the width of each of the nanosheets 22, 26 in the X-direction, but is not limited to this width. The width of each of the nanosheets 21 to 28 (i.e., the gate width of each transistor) in the X-direction may be determined in consideration of the operational stability of the 2-port SRAM circuit.

In the above embodiments and variations, the case where the transistor disposed in the 2-port SRAM cell is the nanosheet FET has been described as an example. However, the present invention is not limited thereto, and the transistor disposed in the 2-port SRAM cell may be a FinFET.

In the above embodiments and variations, the P-type substrates 2, 3 may be P-wells.

According to the present disclosure, in the layout structure of the 2-port SRAM cell where the bit lines are provided in the buried interconnect layer, the semiconductor storage device can be operated at a high speed and its write characteristics can be improved.

What is claimed is:

1. A semiconductor storage device including a 2-port SRAM cell,
the 2-port SRAM cell comprising:
a first transistor having nodes, one of which is connected to a first power source that supplies a first voltage and the other one of which is connected to a first node, and having a gate connected to a second node;
a second transistor having nodes, one of which is connected to the first power source and the other one of which is connected to the second node, and having a gate connected to the first node;
a third transistor having nodes, one of which is connected to the first node and the other one of which is connected to a second power source that supplies a second voltage different from the first voltage, and having a gate connected to the second node;
a fourth transistor having nodes, one of which is connected to the second node and the other one of which is connected to the second power source, and having a gate connected to the first node;
a fifth transistor having nodes, one of which is connected to a first write-bit line and the other one of which is connected to the first node, and having a gate connected to a write-word line;
a sixth transistor having nodes, one of which is connected to a second write-bit line forming a complementary bit line pair together with the first write-bit line and the other one of which is connected to the second node, and having a gate connected to the write-word line;
a seventh transistor having one node connected to the second power source and a gate connected to the second node; and
an eighth transistor having nodes, one of which is connected to the other node of the seventh transistor and the other one of which is connected to a read-bit line, and having a gate connected to a read-word line,
the first write-bit line having a first buried interconnect formed in a buried interconnect layer and extending in a first direction,
the second write-bit line having a second buried interconnect formed in the buried interconnect layer and extending in the first direction,
the write-word line having a first interconnect formed in a first interconnect layer above the buried interconnect layer and extending in a second direction perpendicular to the first direction,
the read-word line having a second interconnect formed in the first interconnect layer and extending in the second direction.

2. The semiconductor storage device of claim 1, wherein
the 2-port SRAM cell further comprises:
a third interconnect formed in a second interconnect layer which is an interconnect layer between the buried interconnect layer and the first interconnect layer, and connected to the first power source, and extending in the first direction; and
a fourth interconnect formed in the second interconnect layer, and connected to the second power source, and extending in the first direction.

3. The semiconductor storage device of claim 2, wherein
the third and fourth interconnects have interconnect widths greater than those of first and second buried interconnects in plan view.

4. The semiconductor storage device of claim 2, wherein
part of the fourth interconnect overlaps with at least one of the first or second buried interconnects in plan view.

5. The semiconductor storage device of claim 2, wherein
the read-bit line has a fifth interconnect formed in the second interconnect layer and extending in the first direction.

6. The semiconductor storage device of claim 2, wherein
the read-bit line has a third buried interconnect formed in the buried interconnect layer and extending in the first direction.

7. The semiconductor storage device of claim 1, wherein
the 2-port SRAM cell further includes:
a second buried power rail formed in the buried interconnect layer, and connected to the second power source, and extending in the first direction; and
a third interconnect formed in a second interconnect layer which is an interconnect layer between the buried interconnect layer and the first interconnect layer, and connected to the first power source, and extending in the first direction.

8. The semiconductor storage device of claim 7, wherein
the read-bit line has a fourth interconnect formed in the second interconnect layer and extending in the first direction.

9. The semiconductor storage device of claim 7, wherein
the third interconnect has an interconnect width greater than those of the first buried interconnect, the second buried interconnect, and the second buried power rail in plan view.

10. The semiconductor storage device of claim 7, wherein
the second buried power rail is shared with a 2-port SRAM cell arranged adjacent to the 2-port SRAM cell in the second direction.

11. A semiconductor storage device inclusing a 2-port SRAM cell,
the 2-port SRAM cell comprising:
a first transistor having nodes, one of which is connected to a first power source that supplies a first voltage and the other one of which is connected to a first node, and having a gate connected to a second node;
a second transistor having nodes, one of which is connected to the first power source and the other one of which is connected to the second node, and having a gate connected to the first node;
a third transistor having nodes, one of which is connected to the first node and the other one of which is connected to a second power source that supplies a second voltage different from the first voltage, and having a gate connected to the second node;
a fourth transistor having nodes, one of which is connected to the second node and the other one of which is connected to the second power source, and having a gate connected to the first node;
a fifth transistor having nodes, one of which is connected to a first write-bit line and the other one of which is connected to the first node, and having a gate connected to a write-word line;
a sixth transistor having nodes, one of which is connected to a second write-bit line forming a complementary bit line pair together with the first write-bit line and the other one of which is connected to the second node, and having a gate connected to the write-word line;
a seventh transistor having one node connected to the second power source, and a gate connected to the second node; and
an eighth transistor having nodes, one of which is connected to the other node of the seventh transistor and the other one of which is connected to a read-bit line, and having a gate connected to a read-word line,
the 2-port SRAM cell further including a second buried power rail formed in a buried interconnect layer, connected to the second power source, and extending in the first direction,
the first write-bit line having a first interconnect formed in a second interconnect layer above the buried interconnect layer and extending in the first direction,
the second write-bit line having a second interconnect formed in the second interconnect layer and extending in the first direction,
the write-word line having a third interconnect formed in a first interconnect layer above the second interconnect layer and extending in a second direction perpendicular to the first direction,
the read-word line having a fourth interconnect formed in the first interconnect layer and extending in the second direction.

12. The semiconductor storage device of claim 11, wherein
the read-bit line has a fifth interconnect formed in the second interconnect layer and extending in the first direction.

13. The semiconductor storage device of claim 11, wherein
the first and second interconnects have interconnect widths greater than that of the second buried power rail in plan view.

14. The semiconductor storage device of claim 11, wherein
the 2-port SRAM cell further comprises:
a first buried power rail formed in the buried interconnect layer, connected to the first power source, and extending in the first direction.

15. The semiconductor storage device of claim 11, wherein
the 2-port SRAM cell further includes:
a sixth interconnect formed in the second interconnect layer, connected to the first power source, and extending in the first direction.

16. The semiconductor storage device of claim 15, wherein
the sixth interconnect is disposed between the first and second interconnects.
